(19) United States
(12) Patent Application Publication
(10) Pub. No.: US 2025/0084803 A1
(43) Pub. Date: Mar. 13, 2025

(54) ENGINE CONTROL UNIT CALIBRATION

(71) Applicant: Secondmind Limited, Cambridge (GB)

(72) Inventors: William COWLEY, Cambridge (GB); Chris MORTER, Cambridge (GB); Henry MOSS, Cambridge (GB); Jesper NIELSEN, Cambridge (GB); Victor PICHENY, Cambridge (GB); Alan SAUL, Cambridge (GB); Samuel WILLIS, Cambridge (GB)

(21) Appl. No.: 18/956,791

(22) Filed: Nov. 22, 2024

Related U.S. Application Data
(63) Continuation of application No. PCT/EP2023/063666, filed on May 22, 2023.

(30) Foreign Application Priority Data
May 26, 2022 (GB) 2207746.5

(51) Int. Cl. F02D 41/24; G01M 15/05

(52) U.S. Cl. CPC F02D 41/2432; F02D 41/2445; F02D 41/248; G01M 15/05

(57) ABSTRACT

A system for calibrating an engine control unit (ECU) for an engine includes a test bed and a data processing system. The test bed includes sensors for measuring values of performance characteristics of the engine, and controllers for adjusting values of variables associated with the operation of the engine. The data processing system includes means for performing operations including determining locations in an input space based on one or more Gaussian process models, obtaining measurements of the engine performance characteristics covering the determined locations in the input space, and updating the one or more Gaussian process models. The operations further include generating, using the one or more Gaussian process models, ECU calibration data for mapping values of the one or more context variables to values of the one or more decision variables.

### CROSS-REFERENCE TO RELATED APPLICATIONS

This application is a continuation under 35 U.S.C. § 120 of International Application No. PCT/EP2023/063666, filed May 22, 2023 which claims priority to GB Application No. 2207746.5, filed May 26, 2022, under 35 U.S.C. § 119(a). Each of the above-referenced patent applications is incorporated by reference in its entirety.

### TECHNICAL FIELD

The present disclosure relates to calibration of an engine control unit (ECU). The disclosure has particular, but not exclusive, relevance to calibration of an ECU for an internal combustion engine.

### BACKGROUND

An engine control unit (ECU) is a ubiquitous component of a modern vehicle engine. The ECU controls values of one or more adjustable parameters associated with the operation of the engine, in dependence on values of one or more context variables derivable from driver inputs and/or environmental inputs.

An ECU typically stores data indicating a mapping from values of one or more context variables to values of one or more decision variables, for example in the form of a lookup table, where the decision variables represent parameters of the engine which are adjustable by the ECU. The mapping is determined during a calibration process prior to deployment of the ECU, and may be updated during the engine's lifetime, for example to alter the performance of the engine or to compensate for other modifications to the vehicle and/or engine. For a given set of values of the context variables, it is desirable for the mapping to yield close-to-optimal values of certain performance characteristics (such as torque) whilst ensuring that other performance characteristics (such as cylinder pressures) satisfy predetermined constraints to ensure safe and prolonged operation of the engine. Due to the complexity of the physics involved and the unavailability of accurate numerical models, ECU calibration is typically performed using empirical data collected in a test bed environment.

ECU calibration is a highly time-consuming and resource-intensive process, due to the large parameter space to be explored and the high resource cost of collecting data from the test bed. The number of data points that can viably be collected is relatively low, leading to high levels of uncertainty about the effects of the individual parameters on the performance characteristics, particularly in the early stages of experimentation. There is thus a need for an efficient and principled method of guiding test bed experiments.

### SUMMARY

According to a first aspect of the present invention, there is provided a system for calibrating an engine control unit (ECU) for an engine. The system includes a test bed and a data processing system. The test bed includes a plurality of sensors for measuring values of a plurality of performance characteristics of the engine, and a plurality of controllers for adjusting values of a plurality of variables associated with the operation of the engine. The plurality of variables include one or more context variables which, when the engine is in use, have values derivable from driving system inputs and/or environmental inputs, and one or more decision variables representing parameters of the engine adjustable by the ECU in dependence on values of the one or more context variables. The data processing system includes means for performing operations including, for a plurality of iterations: determining, based on an objective function, a set of locations in an input space, each location in the input space representing a value of each of the plurality of variables. The objective function is arranged to evaluate outputs of one or more Gaussian process models for a candidate set of locations in the input space. Each of the one or more Gaussian process models has a respective set of trainable parameters is arranged to predict probability distributions for one or more of the plurality of engine performance characteristics for a given location in the input space. The objective function is penalised in dependence on a likeliness predicted by the one or more Gaussian process models of one or more predetermined engine constraints being violated for a given location of the candidate set of locations. The operations further include, for the plurality of iterations: obtaining, using the plurality of sensors and the plurality of controllers, measurements of each of the plurality of engine performance characteristics covering at least a subset of the determined set of locations in the input space; and updating, using the obtained measurements of the plurality of engine performance characteristics, values of the respective set of trainable parameters of each of the one or more Gaussian process models. The operations further include generating, using probability distributions for the plurality of engine performance characteristics predicted by the outputs of the one or more Gaussian process models, ECU calibration data for mapping values of the one or more context variables to values of the one or more decision variables.

By determining the locations in the input space at each iteration based on the outputs of the one or more Gaussian process models, and then updating the one or more Gaussian process models based on measurements collected at the determined locations, the measurements are leveraged to enable the system to explore the parameter space in an efficient and principled manner, reducing the overall number of test bed experiments needed to calibrate the ECU. This is highly desirable in view of the time-consuming and resource-intensive nature of the test bed experiments. The penalised objective function ensures that the system will favour regions of the input space where the engine constraints are more likely to be satisfied, so that more data can be collected at each iteration and the collected data points are more likely to be informative about relevant regions of the input space where the engine can safely operate.

The determined set of locations in the input space may include one or more locations. In some examples, the determined set of locations in the input space includes a plurality of locations in the input space having a predetermined configuration relative to one another. By imposing a predetermined relative configuration on the locations, for example based on which variables can be adjusted most straightforwardly by the test bed controllers, the dimensionality of the search space is effectively the same as if searching for a single location in the input space, which is beneficial for reducing the computational cost and duration of each iteration of the calibration process.

The predetermined configuration may include a sweep across a predetermined range of a first variable of the plurality of variables. The first variable may for example be a first context variable which, when the engine is in use, has a value that is adjustable by a throttle position. For certain experimental setups, context variables that are derivable from the throttle position (or otherwise adjustable by the throttle position) may be varied rapidly during testing, enabling hundreds or even thousands of data points to be collected in a single iteration. In examples where the first context variable represents volumetric efficiency or injected fuel mass, the one or more context variables may include a second context variable representing engine speed. For a given iteration, the predetermined relative configuration may prohibit variation of the second context variable and/or each of the one or more decision variables. It has been found that sweeping through values of the volumetric efficiency or injected fuel mass whilst fixing the engine speed is a particularly efficient method of covering the input space.

For a given iteration, the predetermined relative configuration may impose a common value of a given variable of the plurality of variables, and the common value of the given variable may be updated between iterations in accordance with a low discrepancy sequence. In this way, the corresponding dimension of the input space may be covered uniformly, which is desirable for an efficient optimisation process.

In examples where the performance characteristics of the engine include a torque, and a first context variable has a value adjustable by throttle position, the operations may further include detrending the measurements of the torque with respect to the first context variable. One of the Gaussian process models may be arranged to predict a probability distribution for detrended values of the torque. In this way, dominant variations of the torque with respect to context variables such as engine speed, throttle position, or injected fuel mass, may effectively be subtracted out of the data, improving the sensitivity of the resulting Gaussian process model to fine-scale variations around this trend. Additionally, or alternatively, other engine performance characteristics may be detrended with respect to the first context variable and/or one or more other variables as appropriate.

For a given iteration of the plurality of iterations, determining the set of locations in the input space may include determining, based on the objective function, a respective value for each of the one or more decision variables, the respective values being common across the set of locations in the input space. Whereas it may be necessary/desirable to cover the entirety of the context variable dimensions in the input space, certain values of the decision variables may occur for multiple values of the context variables, or not at all. For this reason, determining promising values of the decision variables based on outputs of the Gaussian process model may be preferable to covering the decision variable dimensions in a systematic manner.

The obtained measurements of the plurality of engine performance characteristics may include a binary flag indicating whether a given engine constraint is violated for each location of said at least subset of the locations. The one or more Gaussian process models may include a classification model for predicting whether the given engine constraint is violated for a given location in the input space, and the objective function may be penalised in dependence on at output of the classification model.

For a given iteration of the plurality of iterations, the operations may further include generating, responsive to the binary flag indicating the given engine constraint being violated for a first location of the determined set of locations, synthetic data indicating that the given engine constraint is violated for one or more further locations in the input space covering a portion of the sweep extending beyond the first location. The updating of values for the set of trainable parameters may include updating, using the generated synthetic data, values for the respective set of the trainable parameters of the classification model. The synthetic data may address an imbalance between the number of positive and negative examples of the binary flag, which may otherwise negatively affect the training of the model, whilst also discouraging the output of the classification model from reverting to its mean function in regions where the engine constraints are violated, which may otherwise result in erroneous (and potentially damaging/dangerous) predictions of the engine constraints being satisfied in such regions.

A first Gaussian process model of the one or more Gaussian process models may include a heteroscedastic likelihood, enabling the model to capture varying levels of observation noise at different regions of the input space. In this case, the operations may further include: obtaining, using the plurality of sensors and the plurality of controllers, measurements of the plurality of engine performance characteristics for a sample of locations in the input space; determining values of a set of trainable parameters of a second Gaussian process model, thereby to fit the second Gaussian process model to the obtained measurements for the sample of locations, the second Gaussian process model corresponding to the first Gaussian process model with a homoscedastic likelihood in place of the heteroscedastic likelihood; and initialising values of the respective set of trainable parameters of the first Gaussian process model based on the determined values of the set of trainable parameters of the second Gaussian process model. In this way, the simpler second Gaussian process model may be initialised using relatively few data points and used to seed the more complex first Gaussian process model.

For a given iteration of the plurality of iterations, obtaining said measurements of each of the engine performance characteristics covering said at least a subset of the determined set of locations in the input space may include obtaining measurements of each of the plurality of engine performance characteristics for a plurality of further locations in the input space, in dependence on the determined set of locations in the input space. The number of measurements may for example be many times higher than the number of determined input locations, providing fine-grained coverage of the input space without the associated increase in computational cost and time taken for each iteration.

The one or more Gaussian process models may include one or more sparse variational Gaussian process models, and the respective set of trainable parameters of each of the one or more sparse variational Gaussian process models may include variational parameters for each of the one or more sparse variational Gaussian process models. The use of sparse variational Gaussian processes may reduce processing and memory demands and may allow the Gaussian process model to remain tractable even when a very large number of data points have been collected. Sparse variational Gaussian processes also facilitate the use of non-conjugate likelihoods, such as heteroscedastic likelihoods and those used for classification.

The engine may be an internal combustion engine, and may include a plurality of cylinders. The one or more decision variables may then include, for a given engine cylinder of the plurality of engine cylinders, a variable intake valve timing, a variable exhaust valve timing, and/or a rate of exhaust gas recirculation.

According to a second aspect, there is provided a method of calibrating an ECU for an engine. The method includes, for a plurality of iterations: determining, based on an objective function, a set of locations in an input space, each location in the input space representing a value of each of a plurality of variables. The plurality of variables include one or more context variables which, when the engine is in use, have values derivable from driving system inputs and/or environmental inputs, and one or more decision variables representing parameters of the engine adjustable by the ECU in dependence on values of the one or more context variables. The objective function is arranged to evaluate outputs of one or more Gaussian process models for a candidate set of locations in the input space. Each of the one or more Gaussian process models has a respective set of trainable parameters and is arranged to predict probability distributions for one or more of the plurality of engine performance characteristics for a given location in the input space. The objective function is penalised in dependence on a likeliness predicted by the one or more Gaussian process models of one or more predetermined engine constraints being violated for a given location of the candidate set of locations. The method further includes, for the plurality of iterations: obtaining measurements of each of the plurality of engine performance characteristics covering at least a subset of the selected set of locations in the input space; and updating, using the obtained measurements of the plurality of engine performance characteristics, values for the respective set of trainable parameters of each of the one or more Gaussian process models. The method further includes generating, using probability distributions for the plurality of engine performance characteristics predicted by the one or more Gaussian process models, ECU calibration data for mapping values of the one or more context variables to values of the one or more decision variables.

According to a third aspect, there is provided a computer program product (such as one or more non-transient storage media) comprising instructions which, when the program is executed by a computer, cause the computer to carry out the above method.

According to a fourth aspect, there is provided a data processing system comprising means for carrying out the above method.

Further features and advantages of the invention will become apparent from the following description of preferred embodiments of the invention, given by way of example only, which is made with reference to the accompanying drawings.

### BRIEF DESCRIPTION OF THE DRAWINGS

FIG. 1 is a schematic block diagram representing a vehicle with an ECU;

FIG. 2 is a schematic block diagram representing a system for calibrating an ECU in accordance with examples;

FIGS. 3A and 3B are plots illustrating a Gaussian process with a heteroscedastic likelihood.

FIG. 4 shows examples of engine operation variables and performance characteristics associated with an engine;

FIG. 5 is a flow diagram representing a method of calibrating an ECU in accordance with examples;

FIG. 6 is a plot illustrating an example of a profile optimisation problem for calibrating an ECU;

FIG. 7 is a plot illustrating sets of locations in an input space in accordance with examples.

### DETAILED DESCRIPTION

Details of systems and methods according to examples will become apparent from the following description with reference to the figures. In this description, for the purposes of explanation, numerous specific details of certain examples are set forth. Reference in the specification to ‘an example’ or similar language means that a feature, structure, or characteristic described in connection with the example is included in at least that one example but not necessarily in other examples. It should be further noted that certain examples are described schematically with certain features omitted and/or necessarily simplified for the ease of explanation and understanding of the concepts underlying the examples.

Embodiments of the present disclosure relate to calibration of an ECU. In particular, embodiments described herein address challenges related to the time-consuming and resource-intensive nature of ECU calibration resulting from the large parameter space covered by the range of possible operating conditions for an engine, and in particular an internal combustion engine.

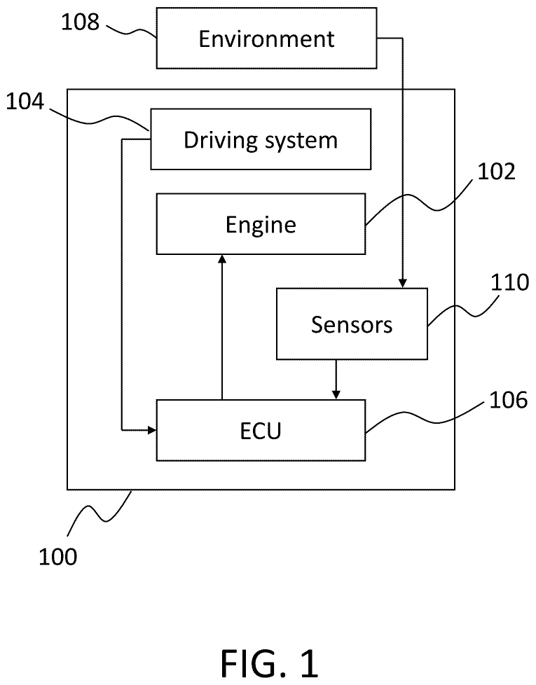

FIG. 1 schematically shows a vehicle 100. The vehicle 100 may be a production car, a racing car, a truck, a lorry, a motorbike, a motorboat, a helicopter, or any other type of powered vehicle. The vehicle 100 includes an engine 102, which in this example is an internal combustion engine, though in other examples a vehicle may include an electric motor, either as an alternative or in addition to an internal combustion engine as in the case of a hybrid vehicle. The vehicle 100 also includes a driving system 104 for controlling certain components of the vehicle 100 such as a steering system, gearbox and brakes, along with certain parameters of the engine 102. The driving system 104 may be a manual driving system configured to receive human input, or may be an automated driving system configured to receive inputs from an autonomous driving agent. Alternatively, the driving system 104 may be configured to receive a combination of manual and computer-generated inputs, for example in the case of an advanced driver assistance system (ADAS). The driving system 104 may control parameters of the engine 102 by controlling mechanical actuators and/or electronic circuitry.

The vehicle 100 further includes an ECU 106 for controlling parameters of the engine which are not directly controllable by the driving system 104. Different ECUs may have control over different parameters of an engine. For example, the ECU 106 may control valve timings in dependence on the injected fuel mass and engine speed. Alternatively, the ECU 106 may control injected fuel mass in dependence on air flow and throttle position, in which case the ECU 106 may be referred to as an electronic engine management system (EEMS). The ECU 106 may be a centralised computing unit or may be a decentralised system of modules controlling respective sets of parameters. For example, an ECU of an electric or hybrid vehicle may include a module for controlling the charging/discharging of rechargeable batteries, and a module for controlling power distribution between motors/engines.

As well as being controlled by the driving system 104 and/or the ECU 106, the operation of the engine may further be affected by external factors relating to the environment 108 in which the engine 102 operates. In the present disclosure, variables which affect the operation of the engine and which are not directly controllable by the ECU 106 may be referred to as context variables. Variables which are directly controllable by the ECU 106 are referred to as decision variables. The function of the ECU 106 is to determine values of one or more decision variables based on values of one or more context variables.

Context variables may have values derivable from the driving system 104, the environment 108, or a combination of both. Relevant environmental factors may for example include the temperature, pressure, and humidity of air external to the engine 102. Examples of context variables may include a parameter directly derivable from the throttle position, which affects the mass of fuel injected into the engine cylinders in a given engine cycle. The injected fuel mass may be a context variable if control of the fuel lines is independent of the ECU 106. Alternatively, the injected fuel mass may be a decision variable controllable by the ECU 106 in dependence on context variables such as mass air flow, oxygen level, and throttle position. Further examples of context variables may include engine speed (i.e. rotation rate), volume air flow, oxygen level, volumetric efficiency, and/or environmental variables such as the temperature of one or more components of the engine 102 or the air ingested by the engine 102. The vehicle 100 may include a number of sensors 110 for measuring the values of various context variables.

Decision variables may include one or more valve timing parameters for controlling timings at which intake and/or exhaust valves of the engine cylinders are opened in an engine cycle. Optimal valve timings are dependent on various context variables, including engine speed, e.g. because valves may be opened earlier in the engine cycle at higher engine speeds to increase air flow into the cylinder. For engines having electronic valve control in place of a conventional camshaft, the adjustable parameters may include one or more valve opening parameters for determining the timing and the extent to which intake and/or exhaust valves are open and closed within an engine cycle. The decision variables may further include a parameter for controlling a rate or proportion at which exhaust gas is recirculated back into the cylinders, and/or an idle speed parameter for controlling an idle speed of the engine. The idle speed affects timing functions for fuel injection, spark events, and valve timing, and may be controlled by a programmable throttle stop or an idle air bypass control stepper motor. In the case of a hybrid engine, the adjustable parameters may include a power distribution parameter for controlling a distribution of power between the internal combustion engine and the electric motor. It will be appreciated that the list of possible context variables and decision variables is not exhaustive, and the exact combination of context variables and decision variables will depend on the design of the engine and ECU.

In accordance with the present disclosure, the ECU 106 may be calibrated to optimise certain engine performance characteristics, such as torque or power, whilst ensuring that other engine performance characteristics, such as mean effective pressure, maximum gas pressure, and knock level for each cylinder, satisfy constraints in order to ensure continued and safe running of the engine 102. More precisely, the aim of the calibration is to determine mappings from context variables to decision variables which result in close-to-optimal values of certain performance characteristics whilst ensuring that other performance characteristics satisfy predetermined inequalities. Combinations of context variables and decision variable which satisfy the predetermined inequalities are referred to as feasible points.

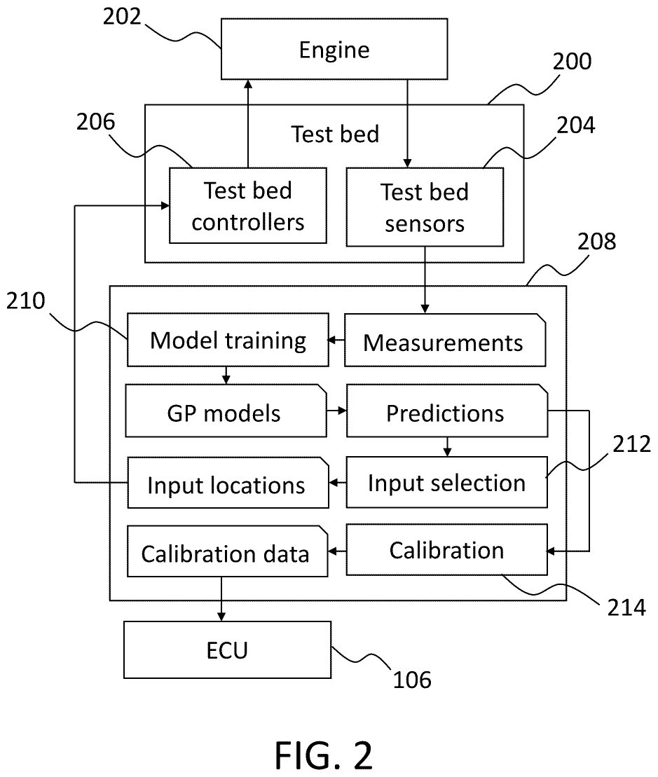

FIG. 2 shows an example of a system for calibrating or tuning the ECU 106. The system includes a test bed 200, which is a controlled environment for performing experiments on an engine 202. The engine 202 in this example is of an identical model to the engine 102 of FIG. 1. The test bed 200 includes test bed sensors 204 and test bed controllers 206. The test bed sensors 204 are arranged to measure performance characteristics of the engine 202, and possibly environmental factors that may affect the performance of the engine 202 in the test bed 200. The test bed controllers 206 are devices capable of controlling the parameters of the engine 202 which, if the engine 202 were in situ in the vehicle 102, would be controllable by the driving system or an ECU. The test bed controllers 206 may further have at least partial control over the environmental factors. It may be possible to precisely control certain environmental factors (for example by adjusting the experimental conditions until the test bed sensors 204 indicate chosen values of the corresponding context variables), whereas it may only be possible to partially control other environmental factors. The test bed controllers 206 may include mechanical actuators, electronic circuits, computer software/hardware components and suchlike, which together are capable of fixing values, at least approximately, for the context variables and decision variables which respectively define input data and output data for the ECU 106.

The test bed sensors 204 and the test bed controllers 206 are coupled, directly or indirectly, to a data processing system 208, which may be a single computing device such as a desktop computer, laptop computer, or server, or may be distributed across multiple computing nodes, for example based at different locations. The data processing system 208 includes one or more processors and memory comprising one or more non-transient storage media holding machine-readable instructions or program code which, when executed by the one or more processors, cause the data processing system 208 to guide experimentation on the test bed 200 in order to collect data revealing how the performance characteristics measured by the test bed sensors 204 depend on values of the context variables and decision variables as set by the test bed controllers 206. When a sufficient volume of such data has been collected, the data processing system 208 may generate ECU calibration data for calibrating the ECU 106. The ECU calibration data represents a mapping of values of the context variables to values of the decision variables for example in the form of a lookup table or other type of data structure. The ECU 106 may be configured to use the lookup table directly to map context variables to decision variables (for example by selecting the nearest entry in the lookup table for a given value of the context variables), or may be configured to interpolate between values of the context variables and/or decision variables to determine a mapping for any permissible set of values of the context variables.

In order to guide the experimentation on the test bed 200, the data processing system 208 includes a number of functional components, any of which may be implemented in hardware, software, or a combination of both. In particular, the data processing system 208 includes a model training component 210, which is configured to train one or more Gaussian process (GP) models for predicting the dependence of performance characteristics of the engine 202 on the context variables and decision variables, based on measurements of the engine performance characteristics obtained from the test bed sensors 204. Values of the context variables, decision variables, and/or engine performance characteristics may be pre-processed, combined, or otherwise adjusted before being processed by the model training component. For example, it may be desirable to normalise at least some of the variables and/or to detrend certain engine performance characteristics such as torque with respect to a dominant context variable such as throttle position, as will be explained in more detail hereinafter.

Each of the one or more GP models may have a large number of trainable parameters, and the aim of training the GP models is to determine values of the trainable parameters for which the GP models best predict values of the performance characteristics, for given values of the context variables and the decision variables (for example as defined using maximum likelihood estimation or maximum aposteriori estimation). The GP models provide a powerful and flexible means of inferring statistical information from the empirical data, and are particularly well-suited to situations in which data is sparse and/or costly to obtain, which is typically the case for test bed experiments on an engine.

Each of the one or more GP models may have one or more outputs corresponding to one or more performance characteristics of the engine. In some examples, the one or more GP models includes an ensemble of multiple GP models each being responsible for predicting values of one or more respective performance characteristics. There may be, for example, ten, twenty, fifty, or a hundred independent GP models, and each of these may be a single output GP model for predicting values of a single performance characteristic. In other examples, a single multi-output GP model is responsible for predicting values of all of the performance characteristics. In further examples still, an ensemble of GP models includes single output GP models for predicting values of some performance characteristics, and multi-output GP models for predicting values of other performance characteristics. For example, certain performance characteristics may correspond to a common attribute but for different cylinders of the engine 202, and may therefore be expected to exhibit a high degree of correlation. A multi-output GP model may then be used to predict the values of these performance characteristics, in order to effectively capture the correlations. The nature of the various outputs of the one or more GP models may depend on the nature of the performance characteristics that the outputs are configured to predict. For example, certain performance characteristics may take the form of binary engine constraints, in which case the corresponding output may be a binary classification output. Other performance characteristics may take continuous values, in which case the corresponding output may be a regression output.

For each GP model, measurements of one or more of the engine performance characteristics for a given input x (having dimensions corresponding to the context and decision variables) are collected in an output y (which may be a scalar or vector quantity). The output y is assumed to be related to the component GP f(x), where f˜GP(μ,K_{θ}). The prior distribution of the GP depends on a kernel K_{θ} (x, x′) parameterised by a set of hyperparameters θ and a mean function μ(x), which may be identically zero in some cases. The relationship between the measured outputs y and the GP f(x) is given by an observation model or likelihood. As will be explained in more detail hereinafter, some GP models may be used for binary classification, in which case an example of appropriate likelihood is a Bernoulli likelihood as given by Equation (1):

$$y \vert x ∼ ℬ ( σ ( f ( x ) ) ) , \qquad ( 1 )$$

where [symbol] (σ)=σ^{y}(1−σ)^{1-y} for class labels y∈{0,1}. The link function σ(·): [symbol] →[0, 1] can be any sigmoid function such as the logistic function or the probit function. The resulting output values of the GP model in this case represent the probability of a binary engine constraint being satisfied. Other observation models, for example based on other generative processes, may be used in place of the Bernoulli likelihood for classification. In some examples, such observation models may depend on one or more latent processes.

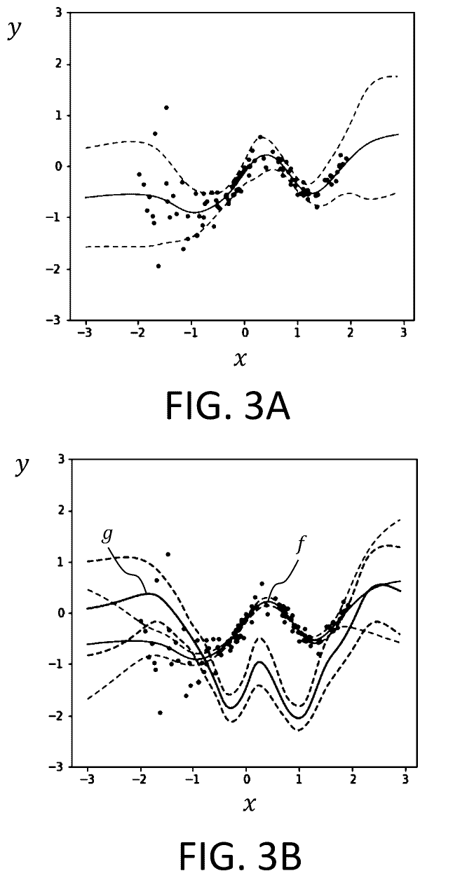

Other GP models may be used to model continuous variables, in which case an example of an appropriate observation model or likelihood is a noise model which assume that the outputs y are observations of the GP corrupted by Gaussian noise such that y|x˜ [symbol] (f(x),∈²) for an (unknown) noise variance ∈². An example of a different observation model uses Student's t-distribution in place of the Gaussian noise, which may be particularly well suited for handling outliers. However, it has been observed by the inventors that at least some of the performance characteristics measured during ECU calibration are not subject to constant noise across the input space, meaning that the standard likelihood models mentioned above may not be suitable for modelling such performance characteristics. To account for this observation, an alternative model may be used in which the standard deviation of the noise at a given input location x is modelled as a function of an auxiliary GP g(x), for example an exponential function of the auxiliary GP, which ensures that the standard deviation is non-negative. The resulting heteroscedastic likelihood model is given by Equation (2):

$$y \vert f ( x ) , g ( x ) ∼ 𝒩 ( f ( x ) , {exp ( g ( x ) )}^{2} ) , \qquad ( 2 )$$

where again, the Gaussian noise distribution may be replaced with a different distribution such as Student's t-distribution. FIG. 3A shows data points representing measurements of a performance characteristic y of a simple model engine at different values of an input variable x. The solid curve shows the mean function of a predictive model for the performance characteristic y based on chained GPs f(x), g(x), and the dashed curves respectively show one standard deviation above and below mean. It is observed that the standard deviation is larger at more extreme values of the input variable, corresponding to greater levels of noise at these regions of the input space. Similar behaviour is observed in real engines, though the regions of greater noise may appear at unpredictable regions of the input space. The solid curves in FIG. 3B show the mean function of the GPs f(x), g (x) as indicated, and the dashed curves show one standard deviation above and below mean.

At least some of the GP models may be implemented using sparse variational GPs, such that the GP models are entirely dependent on a set of inducing outputs at a set of inducing input locations (or alternatively based on a set of inter-domain inducing features), where the inducing outputs have a variational distribution determined by a set of variational parameters, which are trainable parameters of the GP model. The GP models may use a common set of inducing input locations, but this is not essential. The inducing input locations may be selected to correspond to regions in which the input space where the collected data is expected to be most informative, for example in dependence on where data points have been collected, or alternatively the inducing input locations may be treated as a trainable parameter of the GP model. The number of inducing input locations (for example, hundreds or thousands) may be significantly less than the number of data points (for example, tens or hundreds of thousands, or millions), which commensurately decreases processing demands and memory footprint and allows the GP model to remain tractable even when a very large number of data points have been collected. Sparse variational GPs also facilitate the use of non-conjugate likelihoods, such as the Bernoulli likelihood of Equation (1) and the homoscedastic likelihood of Equation (2), which are not compatible with conventional implementations of GP regression.

In a sparse variational GP implementation, the posterior GP p(f|Y) conditioned on the data is approximated by a tractable variational GP q(f) corresponding to a marginalised posterior GP conditioned on the inducing outputs. Values of the trainable parameters of the GP, including the hyperparameters, variational parameters, and optionally inducing input locations, are iteratively updated to determine a maximum aposteriori estimate which can be shown to minimise a Kullback-Leibler divergence between the variational GP and the true posterior GP.

Returning to FIG. 2, the data processing system 208 includes an input selection component 212 arranged to determine locations in an input space having dimensions respectively corresponding to the various context variables and decision variables. The input selection component 212 has the task of selecting input locations which balance exploration (to learn about the effect of the parameters/variables throughout the parameter/variable space) and exploitation (focusing on combinations of parameter/variable values likely to yield favourable performance whilst also obeying constraints). The number of data points that can viably be collected is relatively low, leading to high levels of uncertainty about the effects of the individual parameters on the performance characteristics, particularly in the early stages of experimentation. In accordance with the present disclosure, the input selection component 212 is arranged to determine input locations using Bayesian optimisation, based on an objective function which evaluates outputs of the GP models at candidate sets of locations in the input space.

The objective function may take the form of an acquisition function, for example upper confidence bound, maximum probability of improvement, expected improvement or augmented expected improvement. The purpose of the objective function is to evaluate the outputs of the GP models in a way which addresses the so-called exploration/exploitation dilemma, enabling close-to-optimal ECU mappings to be determined in an efficient manner. As will be explained in more detail hereinafter, the objective function may be penalised in dependence on a likeness predicted by the GP models that one or more engine constraints are violated for at least a subset of a given set of locations in the input space.

The input selection component 212 may be configured to determine sets of locations having a predetermined configuration relative to one another in the input space. For example, candidate sets of locations may only be considered for which the locations have a specified relationship to one another (though the absolute locations will vary between candidate sets). By imposing a predetermined relative configuration on the locations, the dimensionality of the search space is effectively the same as if searching for a single location in the input space, which is beneficial for reducing the computational cost and duration of each iteration of Bayesian optimisation.

By selecting an auspicious relative configuration of input locations, the efficiency of the overall calibration process may be further improved. In particular, certain context variables and/or decision variables may be freely and rapidly adjustable by the test bed controllers 206 whilst measurements are performed on the engine 202, whereas others may be less straightforward to adjust. For example, certain variables that are adjustable by driving system inputs such as throttle position when the engine 202 is in use may be straightforwardly adjustable by the test bed controllers 206. The input selection component 212 may thus be arranged to determine sets of input locations which follow a sweep across a predetermined range or ranges of one or more of these variables, for example whilst keeping values of other variables fixed. Variables which are varied within a given set of input locations may be referred to as local variables. Variables which are fixed within a given set of input locations may be referred to as global variables. When determining which variables to treat as local variables, it is to be noted that values of certain parameters can be varied relatively quickly during testing without compromising the usefulness of the measurements, whilst others must be varied more slowly, as rapid variation of such parameters may place the engine in a transient regime in which useful measurements cannot be obtained.

By fixing the values of certain global variables whilst sweeping through one or more local variables, measurements can be obtained for a given set of input locations in a relatively short period of time. For a distributed server-based implementation of the data processing system 208, with efficient implementations of the GP models as discussed in more detail hereinafter, the determination of each set of input locations may take several minutes, for example 5 minutes, 10 minutes, 20 minutes or 30 minutes. In order to achieve efficient calibration of the ECU 106, it is desirable to reduce the total compute time for the data processing system 208, and also to reduce the total time taken for the testing to be performed. By sweeping through one or more local variables, the time taken per measurement can be reduced, and more data can be collected per iteration of Bayesian optimisation, potentially reducing the number of iterations required and therefore reducing the total time taken to calibrate the ECU 106.

The data processing system 208 includes a calibration component 214, which is arranged to generate ECU calibration data based on values of the engine performance characteristics predicted by the trained GP models. For a given combination of context variables, the calibration component 214 may be arranged to numerically solve an optimisation problem to determine values of the decision variables for which the GP models predict a maximum value of a given performance characteristic (such as torque) whilst also having a high probability of satisfying a given set of engine constraints. The resulting mappings from context variables to decision variables may then be stored, for example in the format of a lookup table, which the ECU 106 can read and/or interpolate to determine a set of decision variables for any permissible set of context variables.

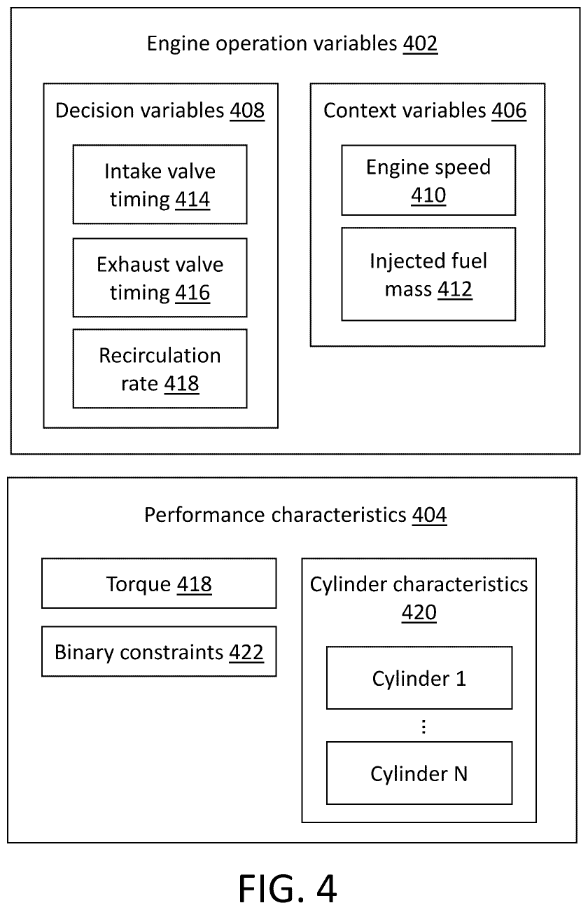

FIG. 4 shows an example of a set of engine operation variables 402 and a set of performance characteristics 404 associated with an engine for which an ECU is to be calibrated using the system of FIG. 2. The engine operation variables 402 in this example include two context variables 406 and three decision variables 408. The context variables 406 in this example are engine speed 410 and injected fuel mass 412. In other examples, the injected fuel mass 412 may be replaced by volumetric efficiency. When the engine is in situ in a vehicle, the injected fuel mass 412 (or volumetric efficiency) is adjustable based on the throttle position. In an example, the test bed controllers 206 may have independent control over the engine speed 410 and injected fuel mass 412. In this case, it may be efficient to treat the injected fuel mass 412 as a local variable and the engine speed 410 as a global variable, and thus to perform tests for a set of input space locations which sweeps over values of the injected fuel mass 412 whilst holding the engine speed 410 constant. It may be possible to sweep over hundreds or thousands of different values of the injected fuel mass 412 in only a few minutes with a fixed value of the engine speed 410, resulting in hundreds or thousands of data points for use in calibrating the ECU.

The decision variables 404 in this example include intake valve timing 414, exhaust valve timing 416, and exhaust gas recirculation rate 418. The variables may be for example be expressed as phase angles relative to a fixed point in an engine cycle. Although the engine may include multiple cylinders (for example four cylinders) and these variables may be defined for each cylinder of the engine, it may be sufficient to determine the values of the decision variables 404 for a first cylinder of the engine, and the values for the remaining cylinders are fixed relative to the values for the first cylinder. The decision variables may be treated as global variables such that values of the decision variables are held constant for a given set of input locations (though this is not essential).

Whilst in the example discussed above a set of locations in the input space involves a sweep across one local context variable whilst holding other variables constant, in other examples a set of locations may include orthogonal sweeps across two or more local variables (thereby covering a rectangle or hyperrectangle in a local variable space), or may include a single sweep in which two or more local variables are varied according to a predetermined relationship (for example, a linear relationship or any other suitable relationship). It will be appreciated that an appropriate configuration for a set of locations in the input space may depend on the type of engine and the capabilities of the test bed.

For examples in which values of one or more context variables and/or decision variables are treated as global variables, the values of at least some of these global variables may be determined as an output of the Bayesian optimisation procedure, whilst others may be determined in dependence on an output of a random, pseudorandom, or quasi-random number generator, or according to another predetermined sequence. Random numbers may be generated by a hardware random number generator. Alternatively, a pseudorandom number generator or deterministic random bit generator (DRBG) may be used to generate a sequence of numbers which approximates a sequence of truly random numbers but is completely determined by an initial seed value. A quasi-random number generator is similar to a pseudorandom number generator but generates a low discrepancy sequence of numbers for which the proportion of terms in the sequence falling in a subinterval is approximately proportional to the length of the subinterval, or in other words the sequence approximates an equidistributed or uniformly distributed sequence. In the context of the present disclosure, a quasi-random number generator can be used to generate values of a variable that cover a given dimension of the input space uniformly in an uncorrelated manner, which is desirable for an efficient optimisation procedure. An example of a low discrepancy sequence on which a quasi-random number generator can be based is a Halton sequence.

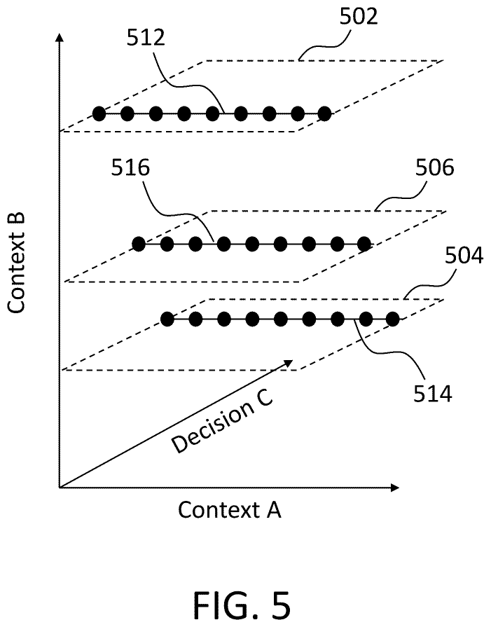

FIG. 5 shows an example of three sets of locations in an input space with dimensions corresponding to two context variables A and B and a single decision variable C. In this example, context variable A is treated as a local variable, whereas context variable B and decision variable C are treated as global variables. Values of context variable B are determined by iterating over a Halton sequence (scaled to match the range of context variable B), with the first three iterations defining planes 502, 504 and 506 respectively. For each plane 502, 504, 506, candidate sets of locations are constrained to having a fixed value of the global decision variable C whilst sweeping across the entire range of the local context variable A. Bayesian optimisation is used to determine a value of global decision variable C, based on outputs of a Gaussian process model evaluated throughout the range of the local context variable A. The first three sets of locations 512, 514, 516 are shown. Although in this example the Bayesian optimisation procedure is only used to determine a value of one decision variable, in reality Bayesian optimisation may be used to determine values of multiple context and/or decision variables, thereby posing a multi-dimensional optimisation problem.

Returning to FIG. 4, the set of performance characteristics 404 includes the torque 418 generated by the engine, along with one or more cylinder characteristics 420 which are evaluated for each cylinder of the engine (for example, each of four cylinders in the case of a four cylinder engine). The cylinder characteristics 420 may include for example mean effective pressure, maximum gas pressure, and knock level. The cylinder characteristics 420 are primarily relevant to determining whether certain engine constraints are satisfied.

The performance characteristics also include one or more binary constraints 422 which can either be satisfied or not satisfied (i.e. violated). The binary constraints 422 may indicate whether safety criteria, noise criteria, emissions criteria, and so on are satisfied. The binary constraints 422 may include hard constraints in which case a sweep across values of an engine operation parameter may have to be stopped immediately if the binary constraint is violated at a given input location. Examples of hard constraints include indications that the engine could be damaged or destroyed if operation of the engine continues under the present conditions. The binary constraints 422 may additionally, or alternatively, include soft constraints for which operation of the engine can continue when the constraint is violated, but this would lead to unacceptable or undesirable effects for the engine when deployed in a driving setting.

In order to be able to determine ECU mappings which result in the binary constraints being satisfied, the one or more Gaussian process models may include one or more binary classification outputs for predicting whether or not the binary constraints are violated. The objective function used for selecting sets of locations in the input space may then be penalised in dependence on the binary classification outputs, to encourage sets of locations to be selected for which there is a low probability of the binary constraints being violated.

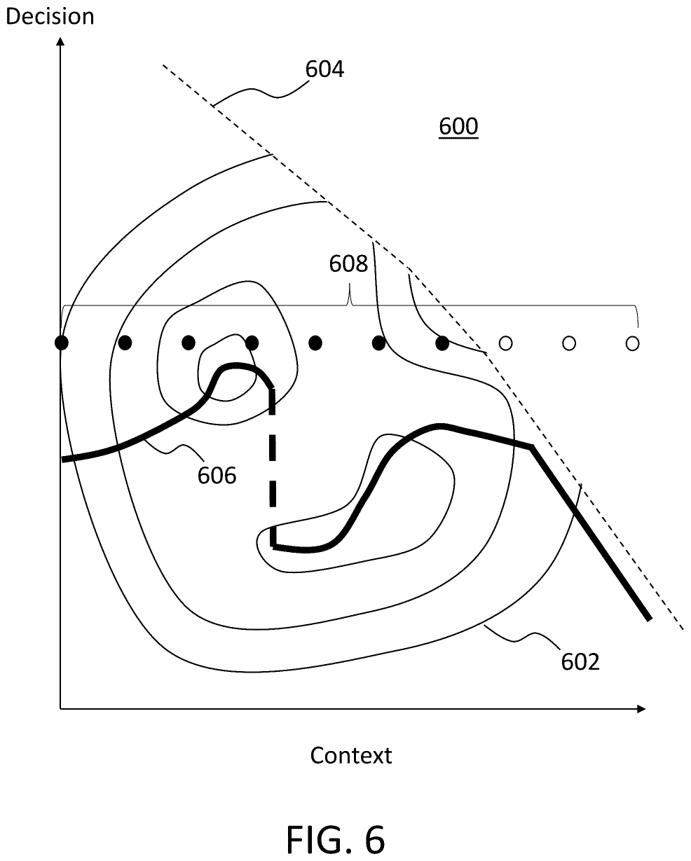

FIG. 6 shows illustrates an example of a two-dimensional input space 600 having a first dimension corresponding to a context variable and a second dimension corresponding to a decision variable. The set of contour lines 602 represent respective values for the torque of an engine, and the dashed line 604 separates a region of the input space 600 for which all engine constraints are satisfied (to the left of the line 604) from a region for which one or more engine constraints are violated (to the right of the line 604). In other words, the dashed line 604 delimits a feasible region of the input space 600. In the present example, an ECU calibration process has the task of determining mappings from values of the context variable to values of the decision variable that maximise the torque within the feasible region of the input space. The thick solid curve 606 shows the best possible value of the decision variable for each value of the context variable. It is observed that the curve 606 follows the contours towards a peak region of the torque, before jumping discontinuously to a different peak region (as shown by the vertical dashed section of the curve 606).

In the present example, the context variable is a local variable whereas the decision variable is a global variable, and the task during each iteration of Bayesian optimisation is to determine a value of the decision variable for which to perform a sweep across the context variable. FIG. 6 shows ten points representing a set of locations 608 in the input space 600. The locations 608 have a common value of the global decision variable and equally spaced values of the local context variable covering a permissible range of values for the context variable. Seven of the locations 608 (shown filled) lie within the feasible region of the input space 600, whereas three of the locations 608 (shown empty) lie outside the feasible region of the input space 600. In this example, the value of the decision variable corresponding to the set of locations 608 is determined at a given iteration of Bayesian optimisation based on an objective function which evaluations of the outputs of the GP models. For example, the objective function may determine the value of the decision variable by assessing the expected improvement (with respect to a predetermined loss function) resulting from that choice of value of the decision variable, compared with a current best estimate for the value of the decision variable. Test bed experiments may then be performed in which engine performance characteristics are measured at a set of locations covering at least a subset of the locations 608. Although the objective function in this example evaluates outputs of the GP models at ten locations in the input space, test bed experiments may be performed on a much larger number of points, for example hundreds, thousands, or tens of thousands of points covering the same range of the context variable as the set of locations 608. In this way, large numbers of data points can be collected, providing fine-grained coverage of regions of the input space 600, without the associated increase in computational cost and time taken for each iteration of Bayesian optimisation. Furthermore, it may not be possible or convenient to obtain measurements at locations corresponding exactly to the determined input locations, for example due to measurement noise and/or because it may not be possible to control certain variables to a sufficiently high level of precision. Nevertheless, the locations of the measurements may approximate the locations 608 and/or lie substantially on a path through the input space as defined by the locations 608, such that the measurements can be said to cover at least a subset of the locations 608.

An example in which test bed experiments are performed only for a subset of the set of locations 608 includes excluding locations 608 for which certain engine constraints (for example, hard engine constraints) are found to be violated. For example, while performing a sweep across the local context variable, the test bed may determine that a binary engine constraint is violated. The sweep across the context variable may be terminated immediately to ensure the engine under testing is not damaged or destroyed. For example, after discovering that a binary constraint is violated to the right of the dashed line 604, the test bed may refrain from taking measurements over a remaining portion of the sweep extending to the right of the dashed line 604. This may result in an imbalance of data for training the classification models, because far more data points will be observed for which the binary constraint is satisfied than for which the binary constraint is violated, particularly where the number of data points collected for each iteration is high, as described above. This may present a problem, as it is typically advantageous to have comparable numbers of positive and negative training examples when training a binary classification model. To remedy this problem, synthetic data may be generated indicating that the engine constraint is violated for one or more further locations in the input space, even when testing has not been performed for these one or more further locations. In the example of FIG. 6, synthetic data may be generated at locations to the right of the line 604, with spacings corresponding to the spacings at which the other data are collected. These “pseudo-data” may be used to redress the data imbalance when training the binary classification models. More generally, pseudo-data may be generated at locations determined in dependence on the predetermined relative configuration of the set of locations in the input space, for example to cover locations for which measurements should be taken but are not taken due to an indication of a binary constraint being violated. As well as balancing data imbalances, the pseudo-data have been found to advantageously prevent the classification models from reverting to their mean functions in non-feasible regions of the input space.

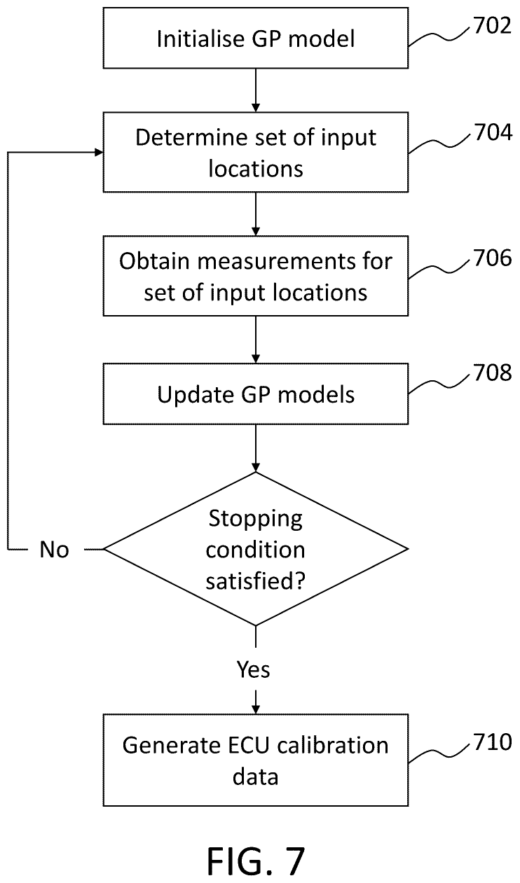

FIG. 7 shows an example of a computer-implemented method 700 of calibrating an ECU in accordance with the present disclosure. The method 700 includes initialising, at 702, one or more GP models. Initialising the one or more GP models includes determining initial values for trainable parameters of the one or more GP models, including for example hyperparameters and variational parameters. The initial values may be determined randomly or by any other suitable method, for example independently of any empirical data or using historic data. The initialising at 702 may further include performing an initial training phase in which an initial dataset is collected from a test bed independently of any Bayesian optimisation step and used to train one or more GP models in order to seed the Bayesian optimisation process. The initial dataset may include measurements of the engine performance characteristics at a relatively small number of sets of input locations (for example, ten, fifty or one hundred sets of input locations).

In an example, the initial training phase includes two training steps. The first training step may include, for one or more GP models, randomly sampling many sets (for example, hundreds or thousands) of hyperparameter values, determining a log likelihood of a relatively small number (for example, tens or hundreds) of data points for each sampled set of hyperparameter values, selecting the set of hyperparameters with the highest log likelihood, and optimising the parameters of the resulting component GP model using maximum a posteriori estimation (for example using gradient-based optimisation with a single natural gradient step for the variational parameters). In an example where one or more of the GP models have a heteroscedastic likelihood, the heteroscedastic likelihood(s) may be replaced with homoscedastic likelihood(s) (i.e. fixed noise) during the initial training step, allowing the variational parameters and hyperparameters of those GP models to be initialised more efficiently using a relatively small number of data points. The parameter values of the auxiliary GPs may be set to default values or set to values dependent on the corresponding homoscedastic GPs. For example, the mean function of an auxiliary GP may be set to the trained likelihood variance of the corresponding homoscedastic GP. Following this first training step, a second training step may be performed in which corresponding full GP models (including heteroscedastic GPs, if used) are trained using stochastic gradient descent or one of its variants such as Adam. The second training step may be performed for a fixed number of iterations or until convergence criteria are satisfied.

The method 700 continues with determining, at 704, a set of locations in the input space. The set of locations is determined in dependence on an objective function which evaluates outputs of the one or more GP models. In some examples, the determined locations share a common value of a global context variable and one or more global decision variables, and cover a sweep over values of a local context variable. The common value of the global context variable may be determined from one iteration to the next by iterating through a Halton sequence or another low discrepancy sequence. The common values of the decision variables may be determined by solving a constrained optimisation problem, as explained below.

The aim of the ECU calibration process is to estimate or approximate a profile optimum which is the optimal mapping of any permissible values of the one or more context variables to optimal values of the one or more decision variables, that is values which maximise the torque whilst ensuring a set of predetermined engine constraints are satisfied. More precisely, the purpose of the ECU calibration process is to determine ECU calibration data which approximates the profile optimum as closely as possible, with a great enough coverage of the context variables that close-to-optimal values of the decision variables can be determined for any permissible values of the context variables, for example by directly reading or interpolating the ECU calibration data.

By decomposing the input location x=(z,u) into one or more decision variables z and one or more context variables u, the profile optimum ϕ may be defined by Equation (3):

$$ϕ ( u ) = {z}^{*} := arg min h ( z , u ) \qquad ( 3 )$$

$$such that {c}_{i} ( z , u ) \leq 0 , i = 1 , … , {d}_{H} + {d}_{B} ,$$

where in an example the loss function h(z,u)=− [symbol] [TQ(z,u)] is minus the expectation of the torque and each of the engine constraints is defined in terms of a respective deterministic function cᵢ(z,u):=cᵢ(x) that depends on evaluations of one or more outputs of the GP model at the input location x. In other examples, the loss function may depend on a different engine performance characteristic, or a combination of performance characteristics, and the loss function may use a different metric such as a quantile in place of the expectation. The engine constraints include d_{H} continuous engine constraints which constrain values of one or more continuous engine performance characteristics, and d_{B} binary engine constraints for which an explicit binary flag is provided. For each of the continuous engine constraints, the function cᵢ(x) may depend on any deterministic function of one or more outputs of the GP models, including the mean, standard deviation, quantiles, or estimated lowest normalised value of the outputs, or a combination of these, and may be aggregated over multiple outputs for example by taking the maximum, minimum or mean values over the outputs. The estimated lowest normalised value for an output y may be defined as 100×( [symbol] (y)−3SD(y))/ [symbol] (y). The function cᵢ(x) may take form cᵢ(x)=ĉᵢ(x)−ξᵢ(x), where cᵢ(x) depends solely on the outputs of the GP model and ξᵢ(x) is independent of the outputs of the GP model. The function ξᵢ(x) may be provided in the form of a lookup table from which values for intermediate values of x can be interpolated. For each of the binary engine constraints, assuming the binary flag data is provided in the form [satisfied, violated]=[0, 1], the constraint may be deemed to be violated if the value of the corresponding binary classification output is greater than 0.5 or another chosen value in the interval (0,1). For these binary constraints, the function cᵢ(x)= [symbol] [bᵢ(x)=1]−0.5, where bᵢ is the value of the corresponding binary classification output.

The multidimensional constrained optimisation problem posed by Equation (3) may be transformed to an unconstrained optimisation problem by penalising the loss function h(z,u) in dependence on the likeliness that a given input location is feasible, as predicted by the GP models. The predicted likeliness that a given input location is feasible may refer to the predicted probability that the given input location is feasible, or may refer to another predicted measure of closeness to certainty that the location is feasible. The probability of an input location being feasible may be estimated as p_{feas}(z,u)=Πᵢ [symbol] [cᵢ(z,u)≤0], where the probability of a given engine constraint being satisfied may be estimated, for example by drawing Monte Carlo samples from the GP models for the continuous engine constraints and using the Gaussian cumulative density function for the binary engine constraints, or using other analytical formulae where available. A penalised loss function may then be defined, for example which is equal to the unpenalised loss function h(z,u) when the probability of feasibility is one, and less than the unpenalised loss function when the probability of feasibility is less than one. In an example, the penalised loss function is equal to the worst possible value of the loss function when the probability of feasibility is zero (though other choices are possible). An example of a suitable penalised loss function is given by Equation (4):

$${loss}_{u} ( z ) = 𝔼 [ h ( z , u ) ] + ( 1 - interp \times ( {h}_{max} ( u ) - 𝔼 [ h ( z , u ) ] ) \qquad ( 4 )$$

where interp is a transition function which controls a transition from zero penalisation to maximum penalisation around a given value of p_{feas}(z,u). The function interp may for example be defined as σ(S×(p_{feas}(z,u)−T))/σ(S×(1−T)), where σ is a sigmoid function, S is a parameter controlling the sharpness of transition, and T is a parameter controlling the value of p_{feas}(z,u) at which the transition occurs. For a given context value u, gradient-based optimisation of the penalised loss function lossᵤ(z) may be performed using the following steps: (1) estimate hₘₐₓ(u) by selecting the largest value of h(z,u) for a large number of points sampled from the decision space; (2) use the estimated value of h(z,u) to evaluate lossᵤ(z) at a large number of points sampled from the decision space; (3) perform gradient-based optimisation (e.g. L-BFGS-B) using the location of the best (lowest) value of the lossᵤ(z) as a starting point.

The objective function used to determine the set of input locations in this example is an acquisition function which evaluates the outputs of the GP model at candidate sets of locations in the input space. The objective function may be defined for a candidate set of Q locations in the input space, for example as a sum over contributions from the Q locations. A specific example of a suitable objective function is given by Equation (5):

$$J ( {\{ {x}_{q} \}}_{q = 1}^{Q} ) = {Σ}_{q = 1}^{Q} A E I ( {x}_{q} , η ( {u}_{q} ) ) \times {\prod }_{i} ℙ ( {c}_{i} ( {x}_{q} ) \leq 0 ) , \qquad ( 5 )$$

where AEI denotes the Augmented Expected Improvement acquisition function with a baseline η(u_{q}) given by current estimates of the profile optimum value. The Augmented Expected Improvement acquisition function is an extension of the classical Expected Improvement acquisition function suitable for noisy function observations, and performs a multiplicative down-weighting of regular expected improvement to account for a diminishing payoff for repeating measurements in the same locations. The Augmented Expected Improvement acquisition function is given by Equation (6):

$$A E I ( x , η ) = E I ( x , η ) \times \frac{\sqrt{𝔼 [ Var ( y ( x ) \vert h ( x ) ]}}{\sqrt{𝔼 [ Var ( y ( x ) \vert h ( x ) ] + Var ( h ( x ) )}} , \qquad ( 6 )$$

where EI denotes the classical Expected Improvement Acquisition function.

The objective function of Equation (5) is penalised in dependence on a predicted probability of each the engine constraints being satisfied at a given location in the set of input locations (or equivalently, in dependence on a predicted probability of each of the engine constraints being violated at a given location). More generally, an objective function may be penalised in dependence on a predicted likeliness of one or more engine constraints being violated for a given input location. The predicted likeliness of an engine constraint being violated may refer to a predicted probability of the engine constraint being violated, or may refer to another measure of closeness to certainty that the engine constraint is violated.

In practice, for each context value u_{q} in the set, the baseline η(u_{q}) appearing in Equation (5) is estimated using gradient-based optimisation of the penalised loss function lossᵤ(z) as described above. The objective function J{x_{q}} is then optimised with respect to the values of the decision variables, in order to determine the set of locations in the input space. The objective function J{x_{q}} may be optimised for example by evaluating J{x_{q}} at a large number of points sampled from the decision space (e.g. uniformly distributed across the decision space), and using selecting best point as a starting point for gradient-based optimisation (e.g. L-BFGS-B).

Although in the examples discussed above the sets of input locations have a predetermined configuration in the input space, in other examples sets of locations may be determined without such a constraint, for example where all of the context and decision variables may be adjusted freely and rapidly during testing. Furthermore, in some examples a set of input locations determined at a given iteration of Bayesian optimisation may include just a single input location.

The method 700 continues with obtaining, at 706, measurements of each of the engine performance characteristics covering at least a subset of the locations determined at 704. To obtain the measurements, the engine is run on the test bed with values of the context and decision variables set to values according to the determined set of locations in the input space. For each location, values of the engine performance characteristics (and any context variables not precisely controllable on the test bed) are measured empirically using test bed sensors. For each measurement, a data point is generated having an input portion representing the values of the context variables and decision variables, and an output portion representing the measured values of the engine performance characteristics. The obtaining of measurements for a given set of input locations may be performed automatically or with some level of human input. Furthermore, as explained above, the measurements may be performed at a far greater density of input locations than is determined at 704 to ensure fine-grained coverage of the relevant region of the input space, and at locations only approximately corresponding to those determined at 704. In cases where one or more engine constraints are found to be violated at a given input location, the taking of measurements may cease at that input location, in which case synthetic data may be generated for any remaining input locations to indicating that the engine constraint is violated at those remaining input locations.

Before proceeding to the next step, the measurements obtained at 706, along with the corresponding values of the context and decision variables, may be pre-processed, combined, normalised or otherwise altered. In particular, measured values of one or more performance characteristics may be detrended with respect to one or more context variables and/or decision variables. For example, the torque of an engine may be strongly affected by the value of one or more variables corresponding to throttle position and/or derivable from throttle position. Accordingly, any GP model tasked with predicting the torque directly will be forced to reproduce this trend, which may reduce the ability of the GP model to predict fine-scale variations around the trend. In order to improve the sensitivity of such a GP model to these fine-scale variations, measurements of the torque may therefore be detrended with respect to these one or more context variables. The detrending may be performed relative to a linear or higher order polynomial function or any other suitable function. It has been found for example that the torque of an engine displays a strong linear relationship with the throttle position, and therefore measurements of the torque may be detrended relative to a linear function of the throttle position. To perform the detrending, least squares estimation may be used to determine a best fit function approximating the relationship between the measurements of the engine performance characteristic and the relevant input variable(s). The best fit function may then be subtracted from the measurements, resulting in detrended measurements which may optionally be rescaled to have a chosen variance (for example, unit variance).

The method 700 proceeds with updating, at 708, the one or more GP models using the measurements obtained at 706. In particular, values of the trainable parameters for each of the one or more of the GP models, including hyperparameters and variational parameters of the GP models and any auxiliary GPs, may be updated using gradient-based optimisation with respect a maximum aposteriori or maximum likelihood objective function. Updating the GP models may include retraining the GP models from scratch (for example using the initialisation method described above) using all of the data collected up to and including the current iteration. Alternatively, values of certain parameters of the GP models, such as kernel hyperparameters and mean functions, may be maintained or copied from the previous iteration (or from the initialisation step 702), which may reduce the number of gradient steps required at each iteration. Values of the variational parameters may also be determined at each iteration in dependence on values of the variational parameters from the previous iterations, though it may not be possible to copy these values over directly due to the inducing input locations changing between iterations (as discussed below).

During the updating step, the set of inducing input locations may be augmented to include additional inducing input locations depending on the set of locations determined at 704. However, this approach results in the number of inducing input locations increasing with the number of iterations, which has the potentially undesirable effect of slowing down the ECU calibration process as more data is collected. Alternatively, the set of inducing input locations may be recalculated at each iteration, enabling the number of inducing input locations to remain constant or approximately constant between iterations. Inducing input locations may for example be placed by indexing the data for example in dependence on the order in which the data points are collected, and selecting equally spaced indices (optionally with an offset that varies between iterations). It will be appreciated that other methods of selecting inducing input locations are possible, for example to ensure that the inducing input locations cover regions corresponding to each of the Bayesian optimisation iterations. Inducing input locations may for example be determined by clustering the input locations of the data points (e.g. using k-means of DBSCAN). In other examples, inducing input locations are treated as trainable parameters of the GP models.

The steps 704-708 continue iteratively until a predetermined stopping condition is satisfied, with new measurements being collected and the GP models being updated at each iteration. The stopping condition may for example include one or more convergence criteria being satisfied, one or more engine performance criteria being satisfied, or a predetermined number of iterations having taken place. At a given iteration, an estimated profile optimum is available to the extent that for a given set of values of the context variables, a set of estimated optimal values of the decision variables, and associated values of the profile optimum, can be determined using gradient-based optimisation. The stopping condition may be dependent on evaluations of the GP models at the estimated profile optimum. For example, the stopping condition may be dependent on a metric comparing a deviation between the determined values of the decision variables (or the corresponding value of the profile optimum) at a given iteration with the values determined at a previous iteration. The stopping condition may be dependent on this deviation falling below a given threshold, indicating that the profile optimum has converged. Examples of suitable metrics include root mean squared difference or mean absolute difference. Alternatively, or additionally, the stopping condition may be dependent on a mean variance of one, some, or all of the GP models at the estimated profile optimum dropping below a given threshold. In this way, the uncertainty estimates built into the GP models can be used to self-assess the quality of the profile optimum estimate at each iteration.

When the stopping condition is satisfied, the method 700 concludes with generating, at 710, ECU calibration data for mapping values of the one or more context variables to values of the one or more decision variables. The ECU calibration data may be in the form of a lookup table or equivalent data structure. Generating the ECU calibration data may involve, for combinations of context variables covering the entire permissible domain of context variables at a sufficiently high resolution, performing gradient-based optimisation using the trained GP models to estimate optimal values of the decision variables, and storing the resulting mappings. Optimal values of the decision variables may be determined using the probability distributions generated by the GP models, for example based on a minimum value of the penalised loss function or any other suitable function of the outputs, for example depending on expectation values and/or quantiles derived from the outputs. The approach may be refined to ensure continuous variation of the decision variables with respect to the context variables where possible, in order to avoid jumping between values unnecessarily in case of the GP outputs exhibiting multimodal behaviour.

It will be appreciated that the test bed experiments may be performed using a control system separate from the data processing system performing the method 700, for example at a different location and possibly controlled by a different commercial entity. For example, the experiments may be performed by a vehicle manufacturer and the data processing system guiding the experimentation may be operated by a third party. In this case, the data processing system guiding the experimentation may process data points from a remote system, and generate recommendations of variable values to be sent to the remote system for further experimentation. The entity operating the data processing system may not need to be provided full details of the experimental setup or even the physical details of all of the parameters, variables, and performance characteristics, provided the relevant constraints on the performance characteristics are provided, allowing the entity performing the experiments to avoid sharing sensitive information.

At least some aspects of the examples described herein with reference to FIGS. 1-7 comprise computer processes or methods performed in one or more processing systems and/or processors. However, in some examples, the disclosure also extends to computer programs, particularly computer programs on or in an apparatus, adapted for putting the disclosure into practice. The program may be in the form of non-transitory source code, object code, a code intermediate source and object code such as in partially compiled form, or in any other non-transitory form suitable for use in the implementation of processes according to the disclosure. The apparatus may be any entity or device capable of carrying the program. For example, the apparatus may comprise a storage medium, such as a solid-state drive (SSD) or other semiconductor-based RAM; a ROM, for example, a CD ROM or a semiconductor ROM; a magnetic recording medium, for example a hard disk; optical memory devices in general; etc.

The above embodiments are to be understood as illustrative examples of the invention. Further embodiments of the invention are envisaged. For example, the methods described herein may be used to calibrate control units for electric motors or hybrid systems, or indeed for any task in which it is required to determine mappings from context variables to decision variables. Furthermore, the systems and methods described herein may be used to calibrate an ECU based on data generated completely or in part using a numerical simulator for an engine or a part of an engine. In such cases, the steps of obtaining measurements of engine performance characteristics may be replaced with obtaining data from the numerical simulator representing simulated values of the engine performance characteristics.

It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

1. A system comprising:
a test bed comprising:
a plurality of sensors for measuring values of a plurality of performance characteristics of an engine; and
a plurality of controllers for adjusting values of a plurality of variables associated with the operation of the engine, the plurality of variables including:
one or more context variables which, when the engine is in use, have values derivable from driving system inputs and/or environmental inputs; and
one or more decision variables representing parameters of the engine adjustable by an ECU in dependence on values of the one or more context variables; and
a data processing system comprising means for performing operations comprising:
for a plurality of iterations:
determining, based on an objective function, a set of locations in an input space, each location in the input space representing a value of each of the plurality of variables,
wherein the objective function is arranged to evaluate outputs of one or more Gaussian process models for a candidate set of locations in the input space, each of the one or more Gaussian process models having a respective set of trainable parameters and being arranged to predict, for a given location in the input space, respective probability distributions for one or more of the plurality of engine performance characteristics,
wherein the objective function is penalised in dependence on a likeliness predicted by the one or more Gaussian process models of one or more predetermined engine constraints being violated for a given location of the candidate set of locations;
obtaining, using the plurality of sensors and the plurality of controllers, measurements of each of the plurality of engine performance characteristics covering at least a subset of the determined set of locations in the input space; and
updating, using the obtained measurements of the plurality of engine performance characteristics, values for the respective set of trainable parameters of each of the one or more Gaussian process models; and
generating, using probability distributions for the plurality of engine performance characteristics predicted by the outputs of the one or more Gaussian process models, ECU calibration data for mapping values of the one or more context variables to values of the one or more decision variables.

2. The system of claim 1, wherein the determined set of locations in the input space comprises a plurality of locations in the input space having a predetermined configuration relative to one another.

3. The system of claim 2, wherein for a given iteration of the plurality of iterations, the predetermined configuration includes a sweep across a predetermined range of a first variable of the plurality of variables.

4. The system of claim 3, wherein the first variable is a first context variable and has a value adjustable by a throttle position.

5. The system of claim 4, wherein:
the first context variable represents volumetric efficiency or injected fuel mass; and
the plurality of variables includes a second context variable representing engine speed.

6. The system of claim 5, wherein for a given iteration of the plurality of iterations, the predetermined configuration prohibits variation of the second context variable.

7. The system of claim 2, wherein:
for a given iteration of the plurality of iterations, the predetermined relative configuration imposes a common value of a given variable of the plurality of variables; and
the common value of the given variable is updated between iterations in accordance with a low discrepancy sequence.

8. The system of claim 1, wherein:
the operations further comprise detrending the measurements of one of the engine performance characteristic with respect to one or more of the plurality of variables; and
one of the Gaussian process models is configured to predict a probability distribution for detrended values of said one of the engine performance characteristics.

9. The system of claim 8, wherein:
the determined set of locations in the input space comprises a plurality of locations in the input space having a predetermined configuration relative to one another;
for a given iteration of the plurality of iterations, the predetermined configuration includes a sweep across a predetermined range of a first variable of the plurality of variables;
the first variable is a first context variable and has a value adjustable by a throttle position; and
said one of the plurality of engine performance characteristics is a torque generated by the engine and said one of the plurality of variables is the first context variable.

10. The system of claim 1, wherein for a given iteration of the plurality of iterations, determining the set of locations in the input space comprises determining, based on the objective function, a respective value for each of the one or more decision variables, the respective values being common across the set of locations in the input space.

11. The system of claim 1, wherein:
the obtained measurements of the plurality of engine performance characteristics include a binary flag indicating whether a given engine constraint is violated for each location of said at least subset of the locations in the input space;
the one or more Gaussian process models include a classification model for predicting whether the given engine constraint is violated for a given location in the input space; and
the objective function is penalised in dependence on an output of the classification model.

12. The system of claim 11, wherein:
the determined set of locations in the input space comprises a plurality of locations in the input space having a predetermined configuration relative to one another;
for a given iteration of the plurality of iterations, the predetermined configuration includes a sweep across a predetermined range of a first variable of the plurality of variables;
for a given iteration of the plurality of iterations, the operations further comprise generating, responsive to the binary flag indicating the given engine constraint being violated for a first location of the determined set of locations, synthetic data indicating that the given engine constraint is violated for one or more further locations in the input space, the one or more further locations covering a portion of the sweep extending beyond the first location; and
the updating of values for the set of trainable parameters comprises updating, using the generated synthetic data, values for the respective set of trainable parameters of the classification model.

13. The system of claim 1, wherein a first Gaussian process model of the one or more Gaussian process models includes a heteroscedastic likelihood.

14. The system of claim 13, wherein the operations further comprise:
obtaining, using the plurality of sensors and the plurality of controllers, measurements of the plurality of engine performance characteristics for a sample of locations in the input space;
determining values of a set of trainable parameters of a second Gaussian process model, thereby to fit the second Gaussian process model to the obtained measurements for the sample of locations, the second Gaussian process model corresponding to the first Gaussian process model with a homoscedastic likelihood in place of the heteroscedastic likelihood; and
initialising values for the respective set of trainable parameters of the first Gaussian process model based on the determined values of the set of trainable parameters of the second Gaussian process model.

15. The system of claim 1, wherein for a given iteration of the plurality of iterations, obtaining said measurements of each of the plurality of engine performance characteristics covering said at least subset of the determined set of locations in the input space comprises obtaining measurements of each of the plurality of engine performance characteristics for a plurality of further locations in the input space, in dependence on the determined set of locations in the input space.

16. The system of claim 1, wherein the one or more Gaussian process models comprise one or more sparse variational Gaussian process models, and the respective set of trainable parameters of each of the one or more sparse variational Gaussian process models includes variational parameters for each of the one or more sparse variational Gaussian processes.

17. The system of claim 1, wherein the engine is an internal combustion engine.

18. The system of claim 17, wherein:
the engine comprises a plurality of cylinders; and
the one or more decision variables include, for a given engine cylinder of the plurality of engine cylinders, a variable intake valve timing, a variable exhaust valve timing, and/or a rate of exhaust gas recirculation.

19. A method of calibrating an ECU for an engine, the method comprising:
for a plurality of iterations:
determining, based on an objective function, a set of locations in an input space, each location in the input space representing a value of each of a plurality of variables,
wherein the plurality of variables comprises:
one or more context variables which, when engine is in use, have values derivable from driving system inputs and/or environmental inputs; and
one or more decision variables representing parameters of the engine adjustable by the ECU in dependence on values of the one or more context variables,
wherein the objective function is arranged to evaluate outputs of one or more Gaussian process models for a candidate set of locations, the one or more Gaussian process models each having a respective set of trainable parameters and being arranged to predict, for a given location in the input space, respective probability distributions for one or more of the plurality of engine performance characteristics,
wherein the objective function is penalised in dependence on a likeliness predicted by the one or more Gaussian process models of one or more predetermined engine constraints being violated for a given location of the candidate set of locations;
obtaining measurements of each of the plurality of engine performance characteristics covering at least a subset of the selected set of locations in the input space; and
updating, using the obtained measurements of the plurality of engine performance characteristics, values for the respective set of trainable parameters of each of the one or more Gaussian process models; and
generating, using probability distributions for the plurality of engine performance characteristics predicted by the one or more Gaussian process models, ECU calibration data for mapping values of the one or more context variables to values of the one or more decision variables.

20. One or more non-transitory storage media comprising instructions which, when the instructions are executed by a computer, cause the computer to carry out operations comprising:
for a plurality of iterations:
determining, based on an objective function, a set of locations in an input space, each location in the input space representing a value of each of a plurality of variables,
wherein the plurality of variables comprises:
one or more context variables which, when engine is in use, have values derivable from driving system inputs and/or environmental inputs; and
one or more decision variables representing parameters of the engine adjustable by the ECU in dependence on values of the one or more context variables,
wherein the objective function is arranged to evaluate outputs of one or more Gaussian process models for a candidate set of locations, the one or more Gaussian process models each having a respective set of trainable parameters and being arranged to predict, for a given location in the input space, respective probability distributions for one or more of the plurality of engine performance characteristics,
wherein the objective function is penalised in dependence on a likeliness predicted by the one or more Gaussian process models of one or more predetermined engine constraints being violated for a given location of the candidate set of locations;
obtaining measurements of each of the plurality of engine performance characteristics covering at least a subset of the selected set of locations in the input space; and
updating, using the obtained measurements of the plurality of engine performance characteristics, values for the respective set of trainable parameters of each of the one or more Gaussian process models; and
generating, using probability distributions for the plurality of engine performance characteristics predicted by the one or more Gaussian process models, ECU calibration data for mapping values of the one or more context variables to values of the one or more decision variables.
